(19) United States
(12) Patent Application Publication
(10) Pub. No.: US 2018/0363133 A1
(43) Pub. Date: Dec. 20, 2018

(54) Method and Apparatus for Void Free SiN Gapfill

(71) Applicant: Applied Materials, Inc., Santa Clara, CA (US)

(72) Inventors: Ranga Rao Arnepalli, Andhra Pradesh (IN); Robert Jan Visser, Menlo Park, CA (US); Pramit Manna, Sunnyvale, CA (US); Abhijit Basu Mallick, Palo Alto, CA (US); Prerna Goradia, Vile Parle (W) (IN)

(21) Appl. No.: 15/625,797

(22) Filed: Jun. 16, 2017

(51) Int. Cl. C23C 16/455; C23C 16/458; C23C 16/46; C23C 16/52; H01L 21/768; H01L 21/762

(52) U.S. Cl. CPC C23C 16/455; C23C 16/458; C23C 16/46; H01L 21/76224; C23C 16/463; H01L 21/76837; C23C 16/52

(57) ABSTRACT

Methods for filling a substrate feature with a seamless silicon nitride gapfill through a radical based hot wire chemical vapor deposition process are described. Also described is an apparatus for performing the radical based hot wire chemical vapor deposition of the silicon nitride gapfill.

### FIELD

Embodiments of the disclosure generally relate to methods for filling substrate features with a seamless silicon nitride gapfill. More particularly, embodiments of the disclosure are directed to methods for filling a substrate feature with a seamless silicon nitride gapfill through a radical based hot wire chemical vapor deposition process. Additional embodiments of the disclosure are directed to an apparatus for performing the radical based hot wire chemical vapor deposition of the silicon nitride gapfill.

### BACKGROUND

The gapfill process is a very important stage of semiconductor manufacturing. Gapfill processes are used to fill high aspect ratio gaps (or features) with an insulating or conducting material. For example, shallow trench isolation, inter-metal dielectric layers, passivation layers, dummy gate, etc. As device geometries shrink and thermal budgets are reduced, defect-free filling of gaps and other features becomes increasingly difficult due to limitations of conventional deposition processes.

Many deposition methods deposit more material on the top region than on the bottom region of a feature. These processes often form a mushroom shape film profile at the top of the feature. As a result, the top part of a feature sometimes pinches off prematurely leaving seams or voids within the feature's lower portions. This problem is more prevalent in smaller features as well as features with higher aspect ratios.

Deposition of silicon nitride has been demonstrated to be a key technology in the semiconductor fabrication industry. However, deposition of SiN into substrate features is difficult without creating seams in the gapfill. Therefore, there is need for a method to create a seamless SiN gapfill.

### SUMMARY

One or more embodiments of the disclosure are directed to a method of substrate processing comprising positioning a substrate on a cooling pedestal in a processing chamber. The substrate has a substrate surface with at least one feature extending into the substrate a distance from the substrate surface. The feature has a bottom and at least one sidewall. The temperature of a filament is raised to provide a hot wire inside the processing chamber. A flow of a reactive gas is directed across the hot wire toward the substrate surface. The reactive gas comprises a first reactive species comprising a silicon precursor and a second reactive species comprising a nitrogen precursor. The hot wire produces a plurality of radicals in the reactive gas. The substrate is exposed to the reactive gas, including the radicals, to form a SiN gapfill in the feature which is substantially seam-free. The cooling pedestal maintains the temperature of the substrate at less than or equal to about 50° C. throughout the reactive gas exposure.

Another embodiment of the disclosure is directed to a method of substrate processing comprising positioning a substrate on a cooling pedestal in a processing chamber at a distance of about 5 cm from a filament. The substrate has a substrate surface with at least one feature extending a distance from the substrate surface into the substrate. The feature has a bottom and at least one sidewall. The temperature of the filament is raised to a range of about 1000° C. to about 1500° C. to provide a hot wire inside the processing chamber. A flow of a reactive gas is directed orthogonal to the hot wire toward the substrate surface. The reactive gas comprises a first reactive species comprising silane and a second reactive species comprising ammonia. The first reactive species is flowed at a rate of less than or equal to about 50 sccm. The hot wire produces a plurality of radicals in the reactive gas. The substrate is exposed to the reactive gas, including the radicals, to provide a substantially seam free SiN gapfill in the feature. The cooling pedestal maintains the temperature of the substrate at less than or equal to about 50° C. throughout the reactive gas exposure.

Other embodiments of the disclosure are directed to a processing chamber. The processing chamber comprises many components including: A chamber body having a plurality of chamber body cooling channels to allow the flow of cooling fluid through the chamber body to cool the chamber body. A chamber lid having a plurality of chamber lid cooling channels to allow the flow of cooling fluid through the chamber lid to cool the chamber lid. The chamber lid includes a gas inlet to direct a flow of gas toward a processing volume within the processing chamber. A substrate support pedestal positioned within the chamber body. The substrate support pedestal includes a plurality of pedestal cooling channels to allow the flow of a cooling fluid to cool the substrate support pedestal during processing. A filament within the processing volume positioned above the substrate support pedestal within the process chamber. A controller coupled to the processing chamber. The controller has a first configuration to heat the filament to a filament temperature, a second configuration to cool the substrate support pedestal to a pedestal temperature, a third configuration to cool the chamber lid and/or chamber body to a chamber temperature, and a fourth configuration to control a flow of gas through the gas inlet and across the filament.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a cross-sectional schematic of a gapfill process in accordance with one or more embodiments of the disclosure;

FIG. 2 shows an exemplary processing chamber in accordance with one or more embodiments of the disclosure; and

FIG. 3 shows an embodiment of a processing chamber in accordance with one or more embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which processing is performed. For example, a substrate surface on which processing can be performed include, but are not limited to, materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface. What a given substrate surface comprises will depend on what materials are to be deposited, as well as the particular chemistry used.

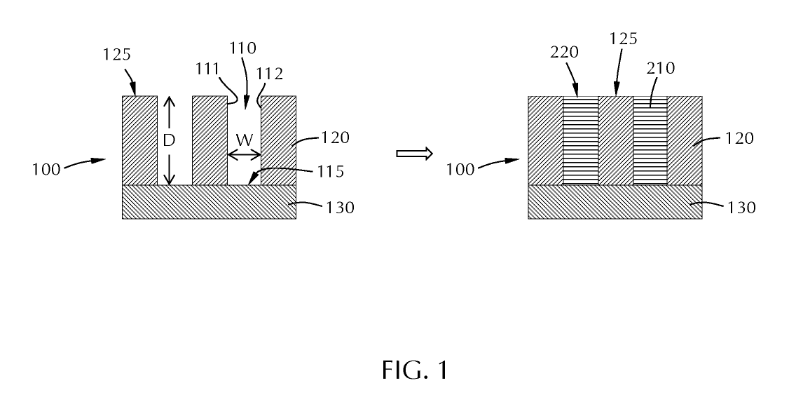

FIG. 1 shows a cross-sectional view of a substrate 100 with two features 110 (e.g. trenches). FIG. 1 shows a substrate having two features for illustrative purposes; however, those skilled in the art will understand that there can be fewer or more features. The shape of the feature 110 can be any suitable shape including, but not limited to, trenches and cylindrical vias. In specific embodiments, the feature 110 is a trench. As used in this regard, the term “feature” means any intentional surface irregularity. In some embodiments, the feature is a trench. For purposes of this disclosure, trenches have a top, two sidewalls extending down from a surface and a bottom. Features can have any suitable aspect ratio (ratio of the depth of the feature to the width of the feature at its opening). In some embodiments, the aspect ratio is greater than or equal to about 5:1, 10:1, 15:1, 20:1, 25:1, 30:1, 35:1 or 40:1. In some embodiments, each sidewall is substantially orthogonal to bottom. In some embodiments, each sidewall is slanted relative to bottom at an angle other than 90 degrees, so that the opening at the surface is greater than at lower portion of the feature.

The substrate 100 may comprised of two materials, a first material 120 and a second material 130. In some embodiments, the first material 120 and the second material 130 are the same. In some embodiments, the first material 120 and the second material 130 are different.

The feature 110 extends into the substrate 100 a distance D from the substrate surface 125 to a bottom 115. The feature 110 has a first sidewall 111 and a second sidewall 112 that define a width W of the feature 110. The open area formed by the sidewalls and bottom are also referred to as a gap. Materials which fill the gap are referred to as gapfill.

One or more embodiments of the disclosure are directed to methods of processing a substrate to provide seam-free SiN gapfill in substrate features through the use of hot wire chemical vapor deposition (HWCVD). A hot wire CVD process is similar to CVD processes commonly known in the art with an additional hot wire component. Without being bound by theory, HWCVD processes make use of radicals generated in one or more of the reactive species when that species is flowed across a hot wire. As used in this specification and the appended claims, the term “hot-wire” means any element that can be heated to a temperature sufficient to generate radicals in a fluid flowed across the element. In some embodiments, the hot wire is one or more metallic filaments. In some embodiments, the hot wire is a filament comprising one or more of tungsten, tantalum or ruthenium.

The substrate processing begins with positioning a substrate with a feature on a cooling pedestal within a processing chamber. The cooling pedestal maintains the temperature of the substrate while the substrate is exposed to reactive gas(es). In some embodiments, the substrate temperature is maintained at less than or equal to about 50° C. In some embodiments, the substrate temperature is maintained at less than or equal to about 25° C.

The processing chamber has chamber walls and a chamber lid. The chamber walls and chamber lid are configured to maintain the chamber temperature during processing. In some embodiments, the chamber lid and chamber walls are cooled to a chamber temperature of less than or equal to about 50° C. In some embodiments, the substrate temperature and the chamber temperature are about the same temperature.

Inside the processing chamber are one or more filaments that can act as a hot wire. The temperature of the one or more filaments is raised by, for example, applying an electrical current through the filament. In some embodiments, the filament temperature is maintained in the range of about 200° C. to about 1500° C. or in the range of about 1000° C. to about 1500° C. or in the range of 1100° C. to about 1400° C. In some embodiments, the filament temperature is maintained at a temperature less than about 1500° C., 1400° C., 1300° C. or 1200° C. It has been surprisingly found that filament temperatures greater than about 1500° C. result in poor film formation. In one or more embodiments, the filament temperature is prevented from going above 1500° C.

The distance between the substrate and the filament can be controlled. In some embodiments, the substrate is positioned at a fixed distance from the filament within the processing chamber. In some embodiments, the distance between the substrate and the filament is in the range of about 1 cm to about 10 cm, or in the range of about 2 cm to about 8 cm, or in the range of about 3 cm to about 5 cm. In some embodiments, the distance between the substrate and the filament is about 3 cm, or about 4 cm, or about 5 cm. In some embodiments, the distance between the substrate (or substrate support) and the filament is less than or equal to about 8 cm, 7 cm, 6 cm or 5 cm.

A flow of reactive gas is directed across the hotwire toward the substrate. In some embodiments, the flow of reactive gas is directed orthogonal to the hotwire. As the reactive gas crosses the hot wire, a plurality of radicals is produced in the reactive gas. The hotwire of some embodiments extends along a plane parallel to the substrate or substrate support and the flow of reactive gas is perpendicular to the substrate or substrate support so that the gas flows orthogonal to the hotwire and not along a length of the hotwire.

A “pulse” or “dose” as used herein is intended to refer to a quantity of a gas that is intermittently or non-continuously introduced into the process chamber. The quantity of a particular compound within each pulse may vary over time, depending on the duration of the pulse. Any particular gas may include a single compound or a mixture/combination of two or more compounds.

The durations for each pulse/dose are variable and may be adjusted to accommodate, for example, the volume capacity of the processing chamber as well as the capabilities of a vacuum system coupled thereto. Additionally, the dose time of a process gas may vary according to the flow rate of the process gas, the temperature of the process gas, the type of control valve, the type of process chamber employed, as well as the ability of the components of the reactive gas to react and form a suitable layer. Dose times may also vary based upon the type of layer being formed and the geometry of the substrate. A dose time should be long enough to provide a volume of compound sufficient to adsorb/chemisorb onto substantially the entire surface of the substrate and form a layer of reactive species thereon.

The reactive gas may be provided in one or more pulses or continuously. The flow rate of the reactive gas can be any suitable flow rate including, but not limited to, flow rates is in the range of about 1 to about 5000 sccm, or in the range of about 2 to about 4000 sccm, or in the range of about 3 to about 3000 sccm or in the range of about 5 to about 2000 sccm or in the range of 5 to about 1000 sccm or in the range of about 5 to 500 sccm or in the range of about 5 to 200 sccm or in the range of about 5 to 100 sccm. The reactive gas can be provided at any suitable pressure including, but not limited to, a pressure in the range of about 5 mTorr to about 25 Torr, or in the range of about 100 mTorr to about 20 Torr, or in the range of about 5 Torr to about 20 Torr, or in the range of about 50 mTorr to about 2000 mTorr, or in the range of about 100 mTorr to about 1000 mTorr, or in the range of about 200 mTorr to about 500 mTorr.

In some embodiments, the reactive gas comprises a carrier gas. The carrier gas may be mixed with the reactive species and can be pulsed or of a constant flow. In some embodiments, the carrier gas is flowed into the processing chamber at a constant flow in the range of about 1 to about 5000 sccm. The carrier gas may be any gas which does not interfere with the film deposition. For example the carrier gas may comprises one or more of argon, helium, hydrogen, nitrogen, neon, or the like, or combinations thereof. In one or more embodiments, the carrier gas is mixed with the reactive species prior to flowing into the process chamber.

The reactive gas comprises a first reactive species and a second reactive species. In some embodiments, the first reactive species and the second reactive species are flowed simultaneously. In some embodiments, the first reactive species and the second reactive species are flowed sequentially. In some embodiments the first reactive gas (e.g., a silane precursor) is flowed into the chamber so that the first reactive gas does not contact the hot wire while the second reactive gas (e.g., ammonia) and a third reactive gas (e.g., hydrogen) is flowed so that each contacts the hot filament. In some of the embodiments, first and second reactive gases (e.g., silane and ammonia) are flowed so that the gases do not contact the hot filament and the third reactive gas (e.g., hydrogen) contacts the hot filament and gets cracked into hydrogen radical and on the way to the substrate the hydrogen radicals react with the first and second reactive gases to from SiN.

The first reactive species comprises a silicon precursor. In some embodiments, the silicon precursor comprises one or more of silane, disilane, a higher order silane or a silyl halide. As used in this specification and the appended claims, the term “higher order silane” means any species of the general formula SiₙH₂ₙ₊₂ where n is greater than 2. As used in this specification and the appended claims, the term “silyl halide” means any species of the general formula SiₙH_{y}X_{2n+2-y}, where y is in the range of 0 to 2n+1 and X comprises one or more of F, Cl, Br or I. In some embodiments, the halide of the silyl halide comprises substantially no fluorine atoms. As used in this regard, the term “substantially no fluorine atoms” means that fluorine atoms make up less than or equal to about 5%, 2% or 1% of the halogen atoms on an atomic basis. In some embodiments, the silicon precursor consists essentially of silane. As used in this regard, the term “consists essentially of” means that the silicon precursor is greater than or equal to about 95%, 98% or 99% of silane on a molar basis.

The first reactive species may be provided in one or more pulses or continuously. The flow rate of the reactive gas can be any suitable flow rate including, but not limited to, flow rates is in the range of about 1 to about 1000 sccm, or in the range of about 2 to about 500 sccm, or in the range of about 3 to about 200 sccm or in the range of about 5 to about 100 sccm or in the range of about 10 to about 50 sccm or in the range of about 15 to 25 sccm. In some embodiments, the flow rate of the first reactive species is less than or equal to about 50 sccm, 45 sccm, 40 sccm, 35 sccm, 30 sccm, 25 sccm, 20 sccm or 15 sccm. The first reactive species can be provided at any suitable pressure including, but not limited to, a pressure in the range of about 5 mTorr to about 25 Torr, or in the range of about 100 mTorr to about 20 Torr, or in the range of about 5 Torr to about 20 Torr, or in the range of about 50 mTorr to about 2000 mTorr, or in the range of about 100 mTorr to about 1000 mTorr, or in the range of about 200 mTorr to about 500 mTorr.

The second reactive species comprises a nitrogen precursor. In some embodiments, the nitrogen precursor comprises one or more of N₂, N₂O, NO₂, NH₃, N₂H₄, or derivatives thereof. In some embodiments, the nitrogen precursor consists essentially of ammonia. As used in this regard, the term “consists essentially of” means that the nitrogen precursor is greater than or equal to about 95%, 98% or 99% of ammonia on a molar basis.

The second reactive species may be provided in one or more pulses or continuously. The flow rate of the reactive gas can be any suitable flow rate including, but not limited to, flow rates is in the range of about 1 to about 1000 sccm, or in the range of about 2 to about 500 sccm, or in the range of about 3 to about 200 sccm or in the range of about 5 to about 100 sccm or in the range of about 10 to about 50 sccm or in the range of about 15 to 25 sccm. In some embodiments, the second reactive species is provided at a flow rate less than or equal to about 50 sccm, 45 sccm, 40 sccm, 35 sccm, 30 sccm, 25 sccm, 20 sccm or 15 sccm. The second reactive species can be provided at any suitable pressure including, but not limited to, a pressure in the range of about 5 mTorr to about 25 Torr, or in the range of about 100 mTorr to about 20 Torr, or in the range of about 5 Torr to about 20 Torr, or in the range of about 50 mTorr to about 2000 mTorr, or in the range of about 100 mTorr to about 1000 mTorr, or in the range of about 200 mTorr to about 500 mTorr.

In some embodiments, a third reactive species is included with one or more of the first reactive species or the second reactive species. The third reactive species can be co-flowed with one or more of the first reactive species or the second reactive species or can be flowed into the processing chamber separately. In some embodiments, the third reactive species comprises hydrogen. The third reactive species may be provided in one or more pulses or continuously. The flow rate of the reactive gas can be any suitable flow rate including, but not limited to, flow rates is in the range of about 1 to about 1000 sccm, or in the range of about 2 to about 500 sccm, or in the range of about 3 to about 200 sccm or in the range of about 5 to about 100 sccm or in the range of about 10 to about 50 sccm or in the range of about 15 to 25 sccm. In some embodiments, the third reactive species is provided at a flow rate less than or equal to about 50 sccm, 45 sccm, 40 sccm, 35 sccm, 30 sccm, 25 sccm, 20 sccm or 15 sccm. The third reactive species can be provided at any suitable pressure including, but not limited to, a pressure in the range of about 5 mTorr to about 25 Torr, or in the range of about 100 mTorr to about 20 Torr, or in the range of about 5 Torr to about 20 Torr, or in the range of about 50 mTorr to about 2000 mTorr, or in the range of about 100 mTorr to about 1000 mTorr, or in the range of about 200 mTorr to about 500 mTorr.

In some embodiments, the third reactive species is exposed to or flowed across the filament and the first reactive species and the second reactive species are not flowed across the filament. In some embodiments, one of the first reactive species, second reactive species or third reactive species is flowed across the hot filament and the other two species are not exposed to the hot filament.

In addition to the foregoing, additional process parameters may be regulated while exposing the substrate to the reactive gas. For example, in some embodiments, the process chamber may be maintained at a pressure of about 0.2 to about 100 Torr, or in the range of about 0.3 to about 90 Torr, or in the range of about 0.5 to about 80 Torr, or in the range of about 1 to about 50 Torr., or in the range of about 2 to about 25 Torr or in the range of about 5 to 20 Torr.

With reference to FIG. 1, a SiN gapfill 210 is formed on the substrate 100. Within the gap, a partial film of gapfill forms along the sidewalls 111 112 and the bottom 115. As this film forms, the potential exists for the formation of a seam if the top of the gap closes before the bottom is filled with gapfill. Higher aspect ratio features are more likely to form a seam during deposition as the film at the top of the feature tends to pinch close so that a void is enclosed within the deposited gapfill. As used in this regard, the term “seam” means any space or void between the sidewalls 111 112 where the volume of the void volume is greater than 1% of the volume of the gap or other feature. In some embodiments, the SiN gapfill deposited is substantially free of seams.

In some embodiments, the SiN gapfill has an atomic nitrogen content in the range of about 5% to about 60%, or about 10% to about 50%, or about 15% to 40% or about 20% to 30% of the total gapfill deposited.

After filling the gap, any over-burden (i.e., SiN deposited on top of the substrate outside of the gap, not shown in FIG. 1) can be removed by a chemical-mechanical planarization (CMP) process. In some embodiments, the CMP process is performed such that the top 220 of the SiN gapfill 210 is about coplanar with the substrate surface 125. In some embodiments, the top 220 of the SiN gapfill 210 is substantially coplanar with the substrate surface 125. As used in this manner, the term “substantially coplanar” means that the plane formed by the substrate surface and the plane formed by the SiN gapfill are within ±5 Å, 4 Å, 3 Å or 2 Å.

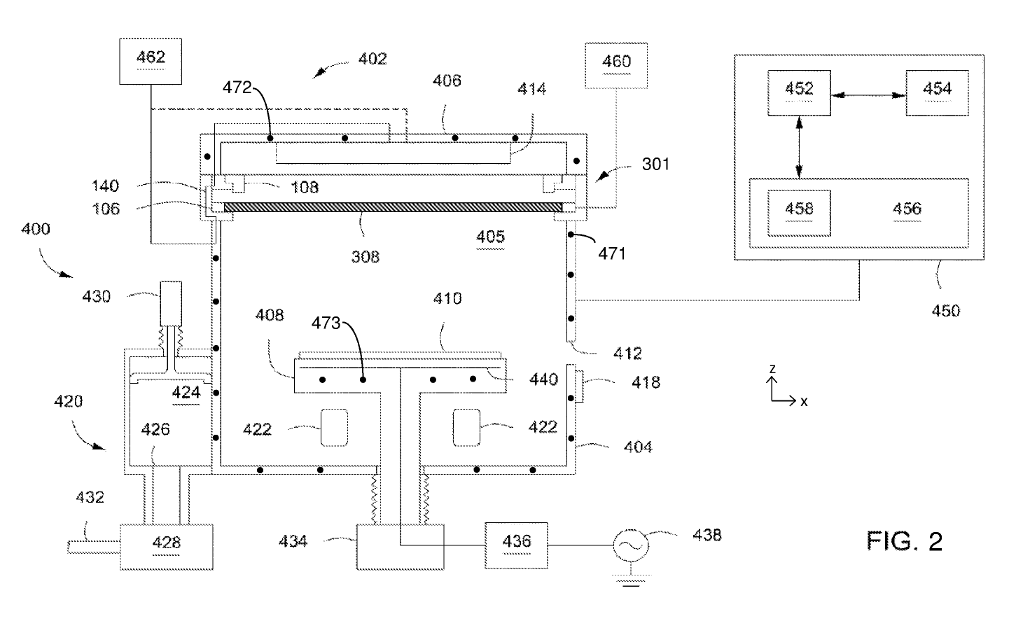

Additional embodiments of this disclosure are directed to a processing chamber. FIG. 2 depicts a system 400 suitable for processing a substrate in accordance with some embodiments of the present disclosure. The system 400 may comprise a controller 450 and a process chamber 402 having an exhaust system 420 for removing excess process gases, processing byproducts, or the like, from the interior of the process chamber 402. Exemplary process chambers may include chemical vapor deposition (CVD) or other process chambers, available from Applied Materials, Inc. of Santa Clara, Calif. Other suitable process chambers may similarly be used.

The process chamber 402 has a chamber body 404 and a chamber lid 406. In some embodiments, the chamber body 404 and chamber lid 406 may include mechanisms for controlling the chamber temperature, such as cooling devices. In some embodiments, the chamber body 404 includes a plurality of chamber body cooling channels 471 to allow a flow of cooling fluid to cool the chamber body 404 during processing. In some embodiments, the chamber lid 406 includes a plurality of chamber lid cooling channels 472 to allow a flow of cooling fluid to cool the chamber lid 406 during processing.

The chamber body 404 and the chamber lid 406 generally enclosing a processing volume 405. The processing volume 405 may be defined, for example, between a substrate support pedestal 408 disposed within the process chamber 402 for supporting a substrate 410 thereupon during processing and one or more gas inlets, such as a showerhead 414 coupled to the chamber lid 406 and/or nozzles provided at predetermined locations. In some embodiments, an apparatus 301 may be coupled to the process chamber 402 disposed between the chamber body 404 and the chamber lid 406. In some embodiments, one or more process gases may be provided to the filaments 308 of the filament assembly (hot wire source) 106 via the showerhead 414 to facilitate a process within the processing volume 405. A power supply 460 (e.g., a DC power supply) is coupled to the apparatus 301 to provide power to the filaments 308.

In some embodiments, the substrate support pedestal 408 may include a mechanism that retains or supports the substrate 410 on the surface of the substrate support pedestal 408, such as an electrostatic chuck, a vacuum chuck, a substrate retaining clamp, or the like (not shown). In some embodiments, the substrate support pedestal 408 may include mechanisms for controlling the substrate temperature, such as cooling devices. In some embodiments, the substrate support pedestal 408 includes a plurality of pedestal cooling channels 473 to allow a flow of cooling fluid to cool the substrate support pedestal 408 during processing.

For example, in some embodiments, the substrate support pedestal 408 may include an RF bias electrode 440. The RF bias electrode 440 may be coupled to one or more bias power sources (one bias power source 438 shown) through one or more respective matching networks (matching network 436 shown). The one or more bias power sources may be capable of producing up to 12,000 W at a frequency of about 2 MHz, or about 13.56 MHz, or about 60 Mhz. In some embodiments, two bias power sources may be provided for coupling RF power through respective matching networks to the RF bias electrode 440 at respective frequencies of about 2 MHz and about 13.56 MHz. In some embodiments, three bias power sources may be provided for coupling RF power through respective matching networks to the RF bias electrode 440 at respective frequencies of about 2 MHz, about 13.56 MHz, and about 60 Mhz. The at least one bias power source may provide either continuous or pulsed power. In some embodiments, the bias power source alternatively may be a DC or pulsed DC source.

The substrate 410 may enter the process chamber 402 via an opening 412 in a wall of the process chamber 402. The opening 412 may be selectively sealed via a slit valve 418, or other mechanism for selectively providing access to the interior of the chamber through the opening 412. The substrate support pedestal 408 may be coupled to a lift mechanism 434 that may control the position of the substrate support pedestal 408 between a lower position (as shown) suitable for transferring substrates into and out of the chamber via the opening 412 and a selectable upper position suitable for processing. The process position may be selected to maximize process uniformity for a particular process. When in at least one of the elevated processing positions, the substrate support pedestal 408 may be disposed above the opening 412 to provide a symmetrical processing region.

A gas supply 462 may be coupled to the apparatus 301 and/or showerhead 414 to provide one or more process gases to the apparatus 301 and/or showerhead 414 for processing. For example, the gas supply 462 may be coupled to the chamber body 404 with the provided gas traveling through the chamber body 404, through the housing 102 (e.g., via conduits 140), and through the chamber lid 406 to the showerhead 414. Alternatively, the gas supply 462 may be coupled directly to the showerhead, as shown in phantom. The apparatus 301 may advantageously be configured to interface with the process chamber 402. Although a showerhead 414 is shown in FIG. 2, additional or alternative gas inlets may be provided such as nozzles or inlets disposed in the ceiling or on the sidewalls of the process chamber 402 or at other locations suitable for providing gases to the process chamber 402, such as the base of the process chamber, the periphery of the substrate support pedestal, or the like.

FIG. 2 shows the filaments 308 arranged in the x-y axis (the y axis is into and out of the page). Regardless of the method used to introduce a gas into the process chamber 402, the gas flows through, not along the plane containing the filaments 308 before the gas is exposed to the substrate. As used in this disclosure, the term “through” means that the incident angle of the gas flow is greater than or equal to 45 degrees relative to the plane which contains the filaments. Referring to FIG. 2, the gas flows along the z-axis and through the filaments 308.

The exhaust system 420 generally includes a pumping plenum 424 and one or more conduits that couple the pumping plenum 424 to the inner volume (and generally, the processing volume 405) of the process chamber 402, for example via one or more inlets 422 (two inlets shown in FIG. 2). A vacuum pump 428 may be coupled to the pumping plenum 424 via a pumping port 426 for pumping out the exhaust gases from the process chamber 402. The vacuum pump 428 may be fluidly coupled to an exhaust outlet 432 for routing the exhaust as needed to appropriate exhaust handling equipment. A valve 430 (such as a gate valve, or the like) may be disposed in the pumping plenum 424 to facilitate control of the flow rate of the exhaust gases in combination with the operation of the vacuum pump 428. Although a z-motion gate valve is shown, any suitable, process compatible valve for controlling the flow of the exhaust may be utilized.

To facilitate control of the process chamber 402 as described above, the controller 450 may be one of any form of general-purpose computer processor that can be used in an industrial setting for controlling various chambers and sub-processors. The memory, or computer-readable medium, 456 of the CPU 452 may be one or more of readily available memory such as random access memory (RAM), read only memory (ROM), floppy disk, hard disk, or any other form of digital storage, local or remote. The support circuits 454 are coupled to the CPU 452 for supporting the processor in a conventional manner. These circuits include cache, power supplies, clock circuits, input/output circuitry and subsystems, and the like.

Processes may generally be stored in the memory 456 as a software routine 458 that, when executed by the CPU 452, causes the process chamber 402 to perform processes of the present disclosure. The software routine 458 may also be stored and/or executed by a second CPU (not shown) that is remotely located from the hardware being controlled by the CPU 452. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine 458 may be executed after the substrate 410 is positioned on the substrate support pedestal 408. The software routine 458, when executed by the CPU 452, transforms the general purpose computer into a specific purpose computer (controller 450) that controls the chamber operation such that the processes are performed.

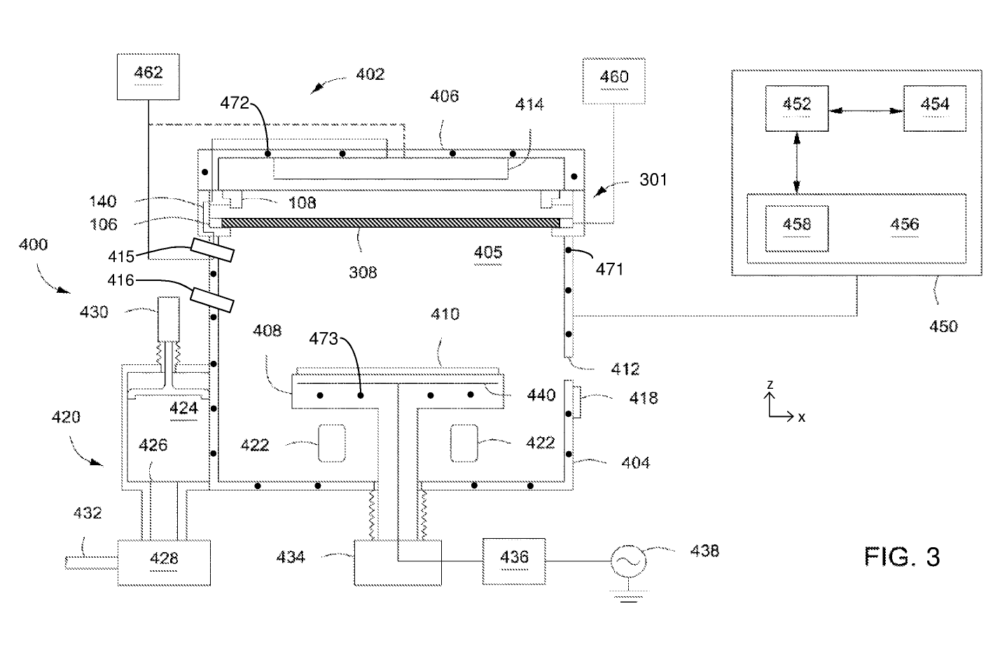

FIG. 3 shows another embodiment of a system 400 like that in FIG. 2. The system 400 in FIG. 3 includes a gas inlet 415 and gas inlet 416 passing through the chamber body 404. The gas inlet 415 and gas inlet 416 can be used to provide a flow of a reactive species that does not pass across the filaments 308. In some embodiments, a first reactive species is in fluid communication with gas inlet 415 (not shown) and is flowed into the processing volume 405 through gas inlet 415 and a second reactive species is in fluid communication with gas inlet 416 (not shown) and is flowed into the processing volume 405 through gas inlet 416 so that the first reactive species and the second reactive species do not pass across filaments 308. A third reactive species can be flowed through showerhead 414 to pass across filaments 308 into the processing volume 405. The third reactive species passing across the filaments 308 will be radicalized or electronically excited to a radical state and can react with the first reactive species, second reactive species and/or substrate 410.

The controller 450 can include one or more of a non-transient memory (e.g., a hard disk drive) or a transient memory (e.g., random access memory (RAM)) which can store, load and/or operate a program to control the processing chamber. The controller 450 can include circuits and electronics configured to interface with and control components of the processing chamber. In some embodiments, the controller 450 is provided with a plurality of configurations which can be operated together, sequentially, or in a programmed order. In some embodiments, the controller 450 has a first configuration to heat the filaments 308 to a filament temperature. In some embodiments, the controller 450 has a second configuration to cool the substrate support pedestal 408 to a pedestal temperature. In some embodiments, the controller 450 has a third configuration to cool the chamber lid 406 and/or chamber body 404 to a chamber temperature. In some embodiments, the controller 450 has a fourth configuration to control a flow of gas through one or more of gas inlet 415, gas inlet 416 or showerhead 414. In some embodiments, the fourth configuration controls the flow of a gas through the showerhead 414 and across the filaments 308. The configurations of the controller 450 can include instruction sets for implementing the process parameters of the components and reactive gases described herein.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

1. A method of processing a substrate, the method comprising:
positioning the substrate on a cooling pedestal in a processing chamber, the substrate having a substrate surface with at least one feature extending into the substrate a distance from the substrate surface, the at least one feature having a bottom and at least one sidewall;
raising the temperature of a filament to provide a hot wire inside the processing chamber;
directing a flow of a reactive gas across the hot wire toward the substrate surface, the reactive gas comprising a first reactive species comprising a silicon precursor and a second reactive species comprising a nitrogen precursor, the hot wire producing a plurality of radicals in the reactive gas; and
exposing the substrate to the reactive gas including the radicals to form a SiN gapfill in the feature,
wherein the cooling pedestal maintains a temperature of the substrate at less than or equal to about 50° C. throughout the exposure and the SiN gapfill is substantially seam free.

2. The method of claim 1, wherein the temperature of the filament is in the range of about 200° C. to about 1500° C.

3. The method of claim 1, wherein the first reactive species is flowed at a rate of less than or equal to about 50 sccm.

4. The method of claim 1, wherein the silicon precursor comprises one or more of silane, disilane, trisilane, tetrasilane, higher order silane or a silyl halide.

5. The method of claim 4, wherein the silicon precursor comprises silane (SiH₄).

6. The method of claim 1 wherein the nitrogen precursor comprises one or more of N₂, N₂O, NO₂, NH₃, N₂H₄, derivatives thereof or combinations thereof.

7. The method of claim 6, wherein the nitrogen precursor comprises ammonia (NH₃).

8. The method of claim 1, wherein the substrate is positioned at a fixed distance from the filament within the processing chamber.

9. The method of claim 8, wherein the fixed distance is in the range of about 3 cm to about 5 cm.

10. A method of processing a substrate, the method comprising:
positioning a substrate on a cooling pedestal in a processing chamber at a distance of about 5 cm from a filament, the substrate having a substrate surface with at least one feature extending a distance from the substrate surface into the substrate, the at least one feature having a bottom and at least one sidewall;
raising the temperature of the filament to a range of about 1000° C. to about 1500° C. to provide a hot wire inside the processing chamber;
directing a flow of a reactive gas orthogonal to the hot wire toward the substrate surface, the reactive gas comprising a first reactive species consisting essentially of silane and a second reactive species consisting essentially of ammonia, the first reactive species flowed at a rate of less than or equal to about 50 sccm, and the hot wire producing a plurality of radicals in the reactive gas; and
exposing the substrate to the reactive gas including the radicals to provide a substantially seam free SiN gapfill in the feature,
wherein the cooling pedestal maintains a temperature of the substrate at less than or equal to about 50° C. throughout the exposure.

11. A processing chamber comprising:
a chamber body having a plurality of chamber body cooling channels to allow a flow of cooling fluid through the chamber body to cool the chamber body;
a chamber lid having a plurality of chamber lid cooling channels to allow a flow of cooling fluid through the chamber lid to cool the chamber lid, the chamber lid including a gas inlet to direct a flow of gas toward a processing volume within the processing chamber;
a substrate support pedestal positioned within the chamber body, the substrate support pedestal including a plurality of pedestal cooling channels to allow a flow of a cooling fluid to cool the substrate support pedestal during processing;
a filament within the processing volume positioned above the substrate support pedestal within the process chamber; and
a controller coupled to the processing chamber, the controller having a first configuration to heat the filament to a filament temperature, a second configuration to cool the substrate support pedestal to a pedestal temperature, a third configuration to cool the chamber lid and/or chamber body to a chamber temperature, and a fourth configuration to control a flow of gas through the gas inlet and across the filament.

12. The chamber of claim 11, wherein the filament is heated to a filament temperature in the range of about 200° C. to about 1500° C.

13. The chamber of claim 12, wherein the filament is heated to a filament temperature in the range of about 1000° C. to about 1500° C.

14. The chamber of claim 11, wherein the substrate support pedestal is cooled to a pedestal temperature of less than or equal to about 50° C.

15. The chamber of claim 14, wherein the substrate support pedestal is cooled to a temperature of less than or equal to about 25° C.

16. The chamber of claim 11, wherein the chamber lid and chamber body are cooled to a chamber temperature of less than or equal to about 200° C.

17. The chamber of claim 11, wherein the substrate support pedestal, chamber lid and chamber body are cooled to about the same temperatures.

18. The chamber of claim 11, wherein the filament is positioned in the range of about 3 cm to about 5 cm above the substrate support pedestal.

19. The chamber of claim 18, wherein the filament is positioned about 5 cm above the substrate support pedestal.

20. The chamber of claim 11, further comprising a second gas inlet configured to provide a flow of reactive gas to the processing volume so that the reactive gas does not flow across the filament.
